(19) United States
(12) Patent Application Publication
(10) Pub. No.: US 2005/0133912 A1
(43) Pub. Date: Jun. 23, 2005

(54) Electrical connection structure

(76) Inventors: Chia-Hui Wu, Hsinhua (TW); Pai-Sheng Cheng, Hsinhua (TW); Wen-Chieh Tu, Hsinhua (TW)

Correspondence Address: RABIN & Berdo, PC, 1101 14TH STREET, NW, SUITE 500, WASHINGTON, DC, 20005, US

(21) Appl. No.: 10/995,141

(22) Filed: Nov. 24, 2004

(30) Foreign Application Priority Data
Dec. 23, 2003 (TW) 92136641

(51) Int. Cl. H01L 29/40

(52) U.S. Cl. 257/734

(57) ABSTRACT

An electrical connection structure for electrically connecting with a chip and a bearing element is provided. The chip has a first surface. The bearing element has a second surface corresponding to the first surface. The electrical connection structure includes two outer contact points on the first surface, M inner contact points on the first surface and correspond to the inner side of the first surface, two outer conducting wires on the second surface, and M inner conducting wires on the second surface and corresponding to the M inner contact points. The chip and the bearing element are electrically connected via the electrical contact between the two outer contact points and the two outer conducting wires, and the electrical connection between the M inner contact points and the M inner conducting wires. M is a positive integer greater than or equal to 2.

This application claims the benefit of Taiwan application Serial No. 92136641, filed Dec. 23, 2003, the subject matter of which is incorporated herein by reference.

### BACKGROUND OF THE INVENTION

1. Field of the Invention

The invention relates in general to an electrical connection structure, and more particularly to an electrical connection structure for electrically connecting with a chip with bearing element.

2. Description of the Related Art

In response to the market demand in slimness, thinness, lightness and compactness, electronic products disposed with liquid crystal display (LCD) are engaged in relevant configuration technology such as tape carrier package (TCP) technology, chip on glass (COG) technology and chip on film (COF) technology, etc.

TCP technology is mainly applied in large-sized LCD panels, while COG technology is mainly in medium to small sized LCD panels. In order to reduce costs, COG is also applied in large sized LCD panels. In recent years, in order to further miniaturize joint interval, researchers are dedicated to the R&D of COF technology for LCD panel to have a higher resolution.

During the liquid crystal display module (LCM) manufacturing process, the TCP technology and the COF technology have a driver IC disposed on a tape or a thin film used for connecting with an LCD panel with a source PCB (or gate PCB), so that the required space for the driver IC to be disposed on the LCD panel or the source PCB can be saved. The COG technology has the driver IC directly disposed on the glass substrate of the LCD panel, so that the bump on the driver IC can be electrically connected to the circuit on the glass substrate directly.

Referring to FIG. 1, a diagram according to a conventional electrical connection structure is shown. In the LCM, the conventional electrical connection structure is for electrically connecting with a chip of the driver IC with a bearing element. The bearing element can be a thin film used in COF, a tape used in TCP, or a glass substrate used in COG.

For the purpose of illustration, the chip has first surface 102 illustrated in dotted lines. Besides, the bearing element has a second surface 104 corresponding to the first surface 102. In contrast to first surface 102, the second surface 104 is illustrated in solid lines.

The conventional electrical connection structure mainly includes a plurality of outer contact points 106 and inner contact points 108 such as bumps, and a plurality of outer conducting wires 110 and inner conducting wires 112 such as inner leads.

The outer contact points 106 are disposed on the outer side of the first surface 102 of the chip. The inner contact points 108 are disposed on the inner side of the first surface 102. Moreover, the inner contact point 108 alternate with the outer contact points 106 with each inner contact point 108 being disposed between two outer contact points 106.

The outer contact points 106 and the inner contact point 108 are connected with the inner conductive connect of the chip. Moreover, the outer contact points 106 and the inner contact point 108 are exposed on the first surface 102 of the chip, wherein the chip can be electrically connected with other elements via the inner contact points 106 and the outer contact points 108 to achieve a better performance.

Furthermore, the outer conducting wires 110 are disposed on the second surface 104 of the bearing element, while the outer conducting wires 110 correspond to the outer contact points 106 disposed on the first surface 102 of the chip. On the other hand, the inner conducting wires 112 are also disposed on the second surface 104, and the inner conducting wires 112 correspond to the inner contact point 108 disposed on the first surface 102.

As shown in FIG. 1, the first surface 102 as well as the outer contact points 106 and the inner contact point 108 disposed on the first surface 102 are illustrated in dotted lines. The second surface 104 as well as the outer conducting wire 110 and the inner conducting wire 112 disposed on the second surface 104 are illustrated in solid lines. Before the chip is electrically connected with the bearing element, the first surface 102 and the second surface 104 are separated from each other. The diagram shows the electrical connection status between the chip and the bearing element when the chip and the bearing element are electrically connected via the first surface 102 and the second surface 104 respectively.

By means of the outer contact points 106 and the inner contact points 108 disposed on the chip as well as the outer conducting wires 110 and the inner conducting wires 112 disposed on the bearing element, the chip and the bearing element can be electrically connected via the electrical contact between the outer contact points 106 and the outer conducting wires 110 as well as the electrical contact between the inner contact point 108 and the inner conducting wires 112.

It can be seen in the diagram that using a conventional electrical connection structure to electrically connect the chip and the bearing element, 13 contact points are positioned on the outer side and inner side of the first surface 102 within the distance of 450 μm from the leftmost contact point to the rightmost contact point disposed on the first surface 102 of the chip, with X1, the interval between each outer contact point 106 and each inner conducting wire 112, being equal to 11.5 μm.

Due to alignment error and further due to X1, the interval between the outer contact points 106 and the inner conducting wire 112, being too small, the outer contact points 106 might electrically contact the inner conducting wire 112, causing short-circuit to occur between the outer contact points 106 and the inner conducting wire 112 when the chip and the bearing element are connected. The short-circuit occurring between the chip and the bearing element due to a narrow interval X1 impedes the performance of LCM.

### SUMMARY OF THE INVENTION

It is therefore an object of the invention to provide an electrical connection structure whose outer contact point of the chip is unlikely to have electrical contact with the inner conducting wire of the bearing element, preventing the occurrence of short-circuit between the chip and the bearing element when the chip and the bearing element jointed together correspondingly.

The invention achieves the above-identified object by providing an electrical connection structure for electrically connecting with a chip and a bearing element. The chip has a first surface, while the bearing element has a second surface corresponding to the first surface. The electrical connection structure includes two outer contact points, M inner contact points, two outer conducting wires, and M inner conducting wires. The two outer contact points disposed on the first surface. The M inner contact points are disposed on the first surface and correspond to the inner side of the first surface on which the two outer contact points are positioned, wherein the M inner contact points are positioned between the two outer contact points, where M is a positive integer greater than or equal to 2. The two outer conducting wires are disposed on the second surface, wherein the two outer conducting wires correspond to the two outer contact points. The M inner conducting wires re disposed on the second surface and correspond to the M inner contact points. The chip and the bearing element are electrically connected via the electrical contact between the two outer contact points and the two outer conducting wires as well as the electrical contact between the M inner contact points and the M inner conducting wires, wherein at least one of the M inner conducting wires is bent and extends along the outer direction of the first surface.

In the above electrical connection structure of the invention, the inner conducting wire can be bent at an angle of 45, 90 or 135 degrees, or the bending deflection of the inner conducting wire can be arc-curved. The two outer contact points and the M inner contact points can be bumps, wherein the bumps can be gold bumps.

Furthermore, in the above electrical connection structure of the invention, the bearing element can be a thin film used in COF, a tape used in TCP, or a glass substrate on COG, while the two outer conducting wires and the M inner conducting wires can be inner leads.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 is a diagram illustrating a conventional electrical connection structure;

FIG. 2 is a diagram illustrating an electrical connection structure according to a preferred embodiment of the invention;

FIG. 3A is a diagram illustrating the status when an inner conducting wire is bent at an angle of 45 degrees;

FIG. 3B is a diagram illustrating the status when an inner conducting wire is bent at an angle of 90 degrees;

FIG. 3C is a diagram illustrating the status when an inner conducting wire is bent at an angle of 135 degrees;

FIG. 3D is a diagram illustrating the status when an inner conducting wire is arc-curved.

### DETAILED DESCRIPTION OF THE INVENTION

The invention is exemplified by a preferred embodiment. However, the preferred embodiment will not limit the scope of protection of the invention. The preferred embodiment is an electrical connection structure under the spirit of the invention. The characteristics of the technology of the invention are disclosed below.

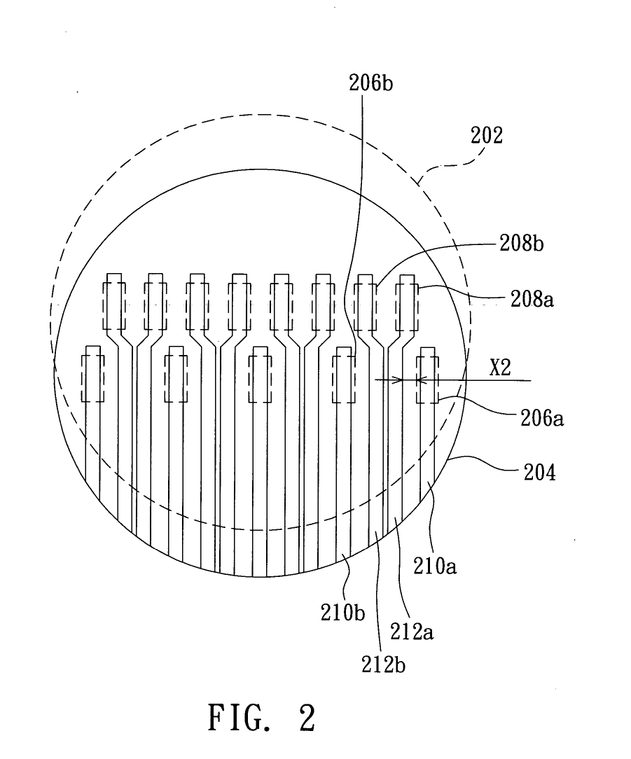

Referring to FIG. 2, a diagram illustrating an electrical connection structure according to a preferred embodiment of the invention is shown. The electrical connection structure of the invention normally electrically connects a chip of driver IC and a bearing element during LCM manufacturing process. The bearing element can be a thin film used in COF, a tape used in TCP, or a glass substrate on COG.

To clearly disclose the characteristics of the structure of the invention, a first surface 202 of a chip in FIG. 2 is illustrated in dotted lines, and so are the elements disposed on first surface 202. Besides, a second surface 204 of a bearing element is illustrated in solid lines and so are the elements disposed on the second surface 204, wherein the second surface 204 corresponds to the first surface 202.

Before the chip and the bearing element are electrically connected, the first surface 202 and the second surface 204 are separated from each other. FIG. 2 illustrates the status when the chip and the bearing element are jointed and electrically connected via the first surface 202 and the second surface 204 respectively.

The electrical connection structure of the invention mainly includes two outer contact points 206a to 206b, M inner contact points 208a to 208b, the two outer conducting wires 210a and 210b, and M inner conducting wires 212a to 212b, where M is an integer greater than or equal to 2. Here, we take M equal to 2 for illustration.

The two outer contact points 206a to 206b are disposed on first surface 202 of the chip and so are the two inner contact points 208a to 208b disposed thereon. Corresponding to the two outer contact points 206a to 206b, the two inner contact points 208a to 208b are positioned on the inner side of the first surface 202. Moreover, the two inner contact points 208a to 208b are disposed inside while the two outer contact points 206a to 206b are disposed outside with the inner contact points 208a to 208b being positioned between the two outer contact points 206a and 206b.

On the other hand, the corresponding outer conducting wires 210a to 210b of the outer contact points 206a to 206b are disposed on the second surface 204 of the bearing element, and so are the inner conducting wires 212a to 212b disposed thereon. Moreover, the inner conducting wires 212a to 212b correspond to the inner contact points 208a to 208b disposed on the first surface 202 of the chip, while the above inner conducting wires 212a to 212b are aligned in parallel with the outer conducting wires 210a to 210b.

The above outer contact points 206a to 206b and the inner contact points 208a to 208b can be bumps normally disposed on the chip, wherein the bumps can be gold bumps. Moreover, the outer conducting wires 210a to 210b and the inner conducting wires 212a to 212b can be inner leads.

As shown in the diagram, The chip and the bearing element can be electrically connected via the electrical connection between the outer contact points 206a to 206b disposed on the first surface 202 of the chip and the outer conducting wires 210a to 210b disposed on the second surface 204 of the bearing element as well as via the electrical connection between the inner contact points 208a to 208b disposed on first surface 202 of the chip and the inner conducting wires 212a to 212b disposed on the second surface 204 of the bearing element. In the above electrical connection structures of the invention, the inner conducting wires 212a to 212b are aligned between the two outer contact points 206a to 206b at an equal distance.

It can be seen in FIG. 2, the characteristic of the electrical connection structure of the invention is that the two inner conducting wires 212a to 212b disposed on the second surface 204 of the bearing element respectively has a bending deflection. Moreover, the inner conducting wires 212a to 212b are bent and extend along the outer direction of the first surface 202 of the chip.

The inner conducting wires are exemplified by the inner conducting wires 212a and 212b. Before the inner conducting wires 212a to 212b disposed on the second surface 204 of the bearing element extend along the outer direction of the first surface 202 of the chip, a bending deflection is formed on the inner conducting wire first, then the inner conducting wires 212a to 212b extend along outer direction of the first surface 202 of the chip.

Due to the bending deflection, a larger interval X2 will respectively be allowed between the inner conducting wires 212a to 212b and the outer contact points 206a to 206b of chip.

In the above preferred embodiment of the invention, the number of the inner contact points positioned between two outer contact points is not necessary to be 2; the number of the inner contact points can be equal to greater than 2 and still within the scope of protection of the invention. Furthermore, the number of the outer contact points positioned between the inner contact points is not necessary to be 1. Besides, the inner conducting wire adjacent to the outer contact points of the preferred embodiment of the invention, a wider interval between the inner conducting wire and the outer contact points can be achieved by having a bending deflection of the inner conductive line formed between the outer contact point and the inner contact point, wherein the deflection of the inner conductive line adjacent to the outer contact point is bent from the vicinity of the inner contact point and bent towards the outer contact points.

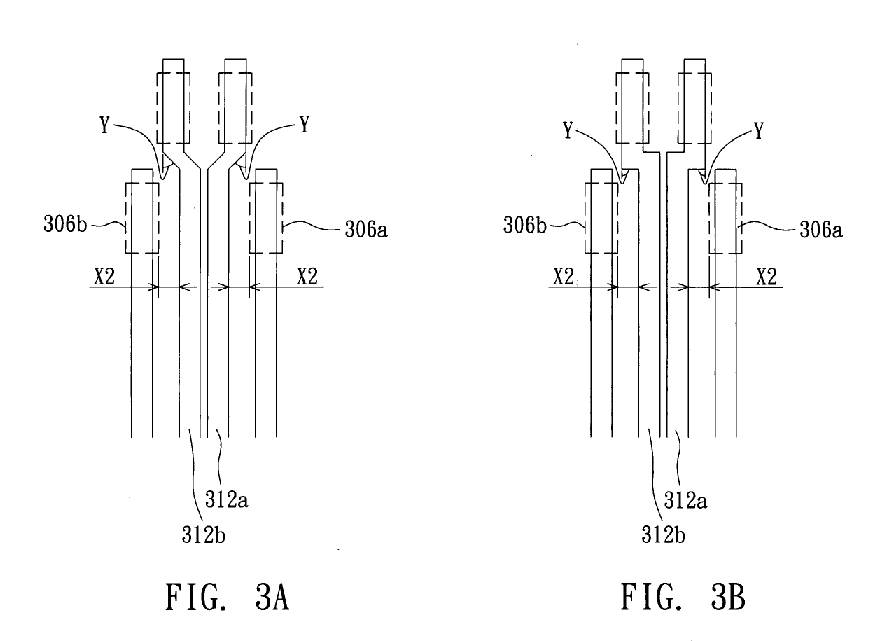

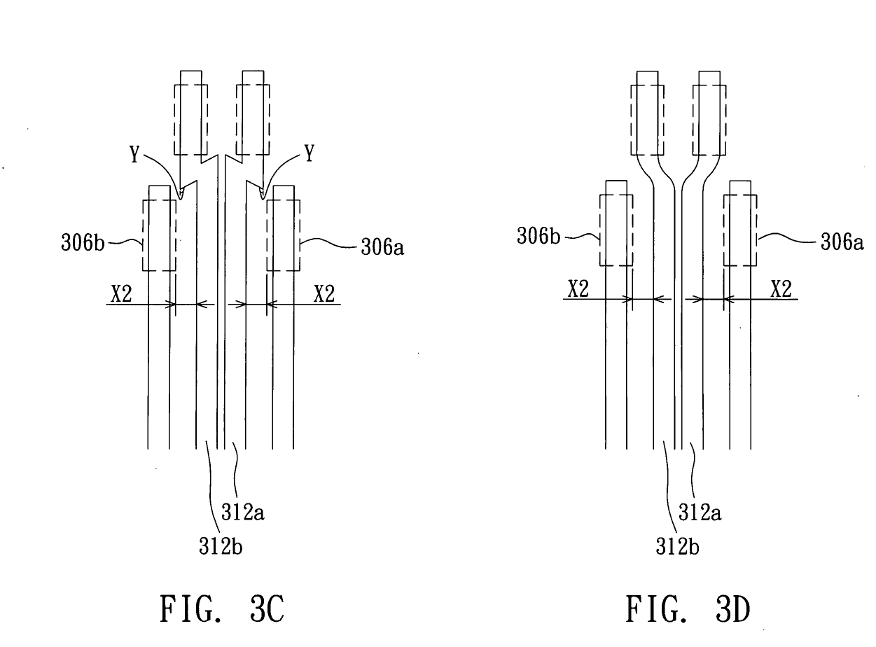

Refer to FIGS. 3A˜3D. FIG. 3A˜FIG. 3C are diagrams illustrating the status when an inner conducting wire is respectively bent at an angle of 45, 90 and 135 degrees, while FIG. 3D is a diagram illustrating the status when an inner conducting wire is arc-curved. It can be seen from the diagrams that no matter the angle Y at the bending deflection on the inner conducting wire is bent at an angle of 45 degrees as in FIG. 3A, 90 degrees as in FIG. 3B or 135 degrees as in FIG. 3C, or the bending deflection on the inner conducting wire is arc-curved as in FIG. 3D, an interval X2 wider than the interval X1 according to prior art can be obtained between the inner conducting wire 312a and the outer contact points 306a as well as between the inner conducting wire 312b and the outer contact points 306b.

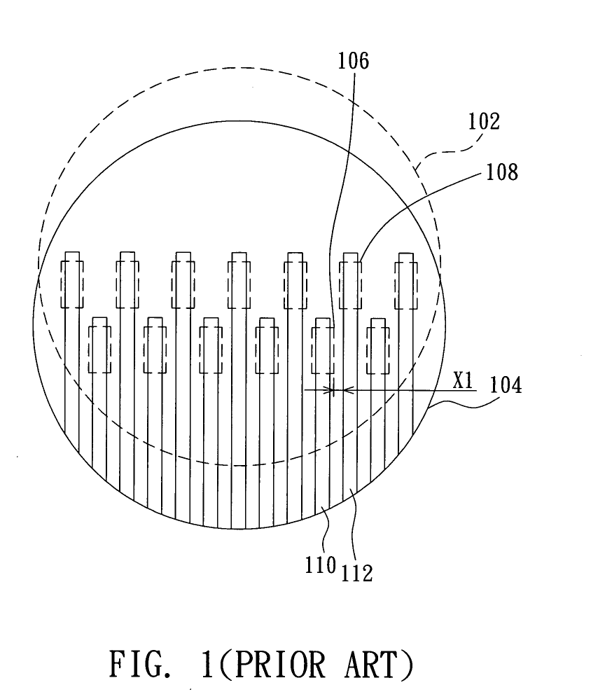

It can be understood from a preferred embodiment according to the invention that the chip and the bearing element are electrically connected via an electrical connection structure of the invention. As shown in FIG. 2, under the same conditions with that of a conventional electrical connection structure as in FIG. 1, there are 13 contact points positioned on the outer side and inner side of the first surface 202 within the distance of 450 μm from the leftmost contact point to the right most contact point disposed on the first surface 202 of the chip, wherein X2, the interval between each outer contact point, the outer contact points 206a for instance, and each inner conducting wire, the inner conducting wire 212a for instance, can be enlarged to be 14 μm. The width of X2 is much wider than that of X1, i.e., 11.5 μm, the interval between each outer contact point 106 and each inner conducting wire 112 in FIG. 1.

Therefore, the electrical connection structure according to the invention disclosed above and the set of chip and bearing element having the electrical connection structure have the following advantages. With the bending deflection on the inner conducting wire, X2, the interval between the outer contact points and the inner conducting wire can be largely widened. When the chip and the bearing element are connected, the outer contact points 206a will be less likely to have electrical contact with the inner conducting wire 212a, and so will the short-circuit between the outer contact points 206a and the inner conducting wire 212a be less likely to occur. Consequently, the LCM can have a better performance.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

1. An electrical connection structure for electrically connecting with a chip and a bearing element, the electrical connection structure comprising:
a first surface;
a second surface;
two outer contact points disposed on the first surface;
M inner contact points disposed on the first surface and corresponding to the two outer contact points positioned on the inner side of the first surface, wherein the M inner contact points are positioned between the two outer contact points, where M is a positive integer greater than or equal to 2;
two outer conducting wires disposed on the second surface, wherein the two outer conducting wires correspond to the two outer contact points; and
M inner conducting wires disposed on the second surface and corresponding to the M inner contact points, wherein the chip and the bearing element are electrically connected via the electrical contact between the two outer contact points and the two outer conducting wires and the electrical contact between the M inner contact points and the M inner conducting wires.

2. The electrical connection structure according to claim 1, wherein at least one of the M inner conducting wires is bent and extends along the outer direction of the first surface.

3. The electrical connection structure according to claim 2, wherein the inner conducting wire is bent at an angle of 45, 90 or 135 degrees.

4. The electrical connection structure according to claim 2, wherein the inner conducting wire is arc-curved.

5. The electrical connection structure according to claim 2, wherein the two outer contact points and the M inner contact points are a plurality of bumps.

6. The electrical connection structure according to claim 5, wherein the bumps are a plurality of gold bumps.

7. The electrical connection structure according to claim 2, wherein the bearing element is a thin film used in chip on film (COF) technology, while the two outer conducting wires and the M inner conducting wires are a plurality of inner leads.

8. The electrical connection structure according to claim 2, wherein the bearing element is a tape used in tape carrier package (TCP) technology, while the two outer conducting wires and the M inner conducting wires are a plurality of inner leads.

9. The electrical connection structure according to claim 2, wherein the bearing element is a glass substrate used in chip on glass (COG) technology.

10. The electrical connection structure according to claim 1, wherein the M inner conducting wires and the two outer conducting wires are aligned in parallel.

11. The electrical connection structure according to claim 10, wherein the M inner conducting wires are aligned between the two outer contact points at an equal distance.

12. The electrical connection structure according to claim 1, wherein M is equal to 2 and at least one of the M inner conducting wires is bent.

13. The electrical connection structure according to claim 12, wherein the inner conducting wire is bent at angle of 45, 90 or 135 degrees.

14. The electrical connection structure according to claim 13, wherein the M inner conducting wires are aligned between the two outer contact points at an equal distance.

15. A set of chip and bearing element, comprising:
a chip having a first surface, wherein the chip comprises:
two outer contact points disposed on the first surface; and
M inner contact points disposed on the first surface and corresponding to the two outer contact points positioned on the inner side of the first surface, wherein the M inner contact points are positioned between the two outer contact points, where M is a positive integer greater than or equal to 2; and
a bearing element having a second surface corresponding to the first surface, wherein the bearing element comprises:
two outer conducting wires disposed on the second surface, wherein the two outer conducting wires correspond to the two outer contact points; and
M inner conducting wires disposed on the second surface and corresponding to the M inner contact points, wherein the chip and the bearing element are electrically connected via the electrical contact between the two outer contact points and the two outer conducting wires and the electrical contact between the M inner contact points and the M inner conducting wires.

16. The set of chip and bearing element according to claim 15, wherein at least one of the M inner conducting wires is bent and extends towards the outer direction of the first surface.

17. The set of chip and bearing element according to claim 16, wherein the inner conducting wire is bent at an angle of 45, 90 or 135 degrees.

18. The set of chip and bearing element according to claim 16, wherein the inner conducting wire is arc-curved.

19. The set of chip and bearing element according to claim 16, wherein the two outer contact points and the M inner contact points are a plurality of bumps.

20. The set of chip and bearing element according to claim 19, wherein the bumps are a plurality of gold bumps.

21. The set of chip and bearing element according to claim 16, wherein the bearing element is a thin film used in COF technology, while the two outer conducting wires and the M inner conducting wires are a plurality of inner leads.

22. The set of chip and bearing element according to claim 16, wherein the bearing element is a tape used in TCP technology, while the two outer conducting wires and the M inner conducting wires are inner leads.

23. The set of chip and bearing element according to claim 16, wherein the bearing element is a glass substrate used in COG technology.

24. The set of chip and bearing element according to claim 15, wherein the M inner conducting wires and the two outer conducting wires are aligned in parallel.

25. The set of chip and bearing element according to claim 24, wherein the M inner conducting wires are aligned between the two outer contact points at an equal distance.

26. The set of chip and bearing element according to claim 15, where M is equal to 2 and at least one of the M inner conducting wires is bent.

27. The set of chip and bearing element according to claim 26, wherein the inner conducting wire is bent at an angle of 45, 90 or 135 degrees.

28. The set of chip and bearing element according to claim 27, wherein the M inner conducting wires are aligned between the two outer contact points at an equal distance.
